(19) United States
(12) Patent Application Publication
(10) Pub. No.: US 2026/0003203 A1
(43) Pub. Date: Jan. 1, 2026

(54) LASER PEN

(71) Applicant: Ningbo SINCERE Holding Group Co., Ltd., Ningbo (CN)

(72) Inventor: Charley LU, Ningbo (CN)

(73) Assignee: Ningbo SINCERE Holding Group Co., Ltd., Ningbo (CN)

(21) Appl. No.: 18/802,113

(22) Filed: Aug. 13, 2024

(30) Foreign Application Priority Data
Jun. 28, 2024 (CN) 2024215209771

(51) Int. Cl. G02B 27/20; H01S 5/068

(52) U.S. Cl. CPC G02B 27/20; H01S 5/06825

(57) ABSTRACT

The present application provides a laser pen and relates to the technical field of laser pens. The laser pen includes a tube body and a base, where the tube body is of a hollow structure, and the base is connected to a first end of the tube body, to form an accommodating cavity; a laser diode configured to transmit a laser beam is disposed in the accommodating cavity, and the laser diode emits the laser beam from a second end of the tube body; the first end of the tube body is provided with at least one through groove, the through groove is provided with a bending portion, and one end thereof is communicated with the outside; and a side wall of the base is provided with a protrusion portion corresponding to the through groove.

### CROSS-REFERENCE TO RELATED APPLICATIONS

The application claims priority to Chinese patent application No. 2024215209771, filed on Jun. 28, 2024, the entire contents of which are incorporated herein by reference.

### TECHNICAL FIELD

The present invention relates to the technical field of laser pens, and specifically, to a laser pen.

### BACKGROUND

Generally, a laser pen is externally composed of three parts: a tube head, a tube body, and a tail cover. The tube head and the tail cover are connected to two opposite ends of the tube body respectively. The tube body is internally provided with elements such as a battery, a circuit board, and a laser diode that are electrically connected to each other. Elements such as the battery and the circuit board supply electric energy to the laser diode, and the laser diode emits a laser beam from the tube head.

According to an existing laser pen, a tail cover is generally in threaded connection with a tube body, but a threaded connection manner results in easy loosening and separation between the tail cover and the tube body, thereby resulting in easy falling-off of internal elements of the tube body.

### SUMMARY

A purpose of the present invention is to provide a laser pen that can prevent loosening and separation between a base and a tube body and falling-off, thereby improving connection stability between the base and the tube body and making assembly simple and convenient.

Embodiments of the present invention are implemented as follows:

According to an aspect of the present invention, a laser pen is provided and includes a tube body and a base, where the tube body is of a hollow structure, and the base is connected to a first end of the tube body, to form an accommodating cavity; a laser diode configured to transmit a laser beam is disposed in the accommodating cavity, and the laser diode emits the laser beam from a second end of the tube body; the first end of the tube body is provided with at least one through groove, the through groove is provided with a bending portion, and one end thereof is communicated with the outside; and a side wall of the base is provided with a protrusion portion corresponding to the through groove, and the protrusion portion can be clamped in the bending portion of the through groove to enable the base to be connected to the tube body.

Optionally, the through groove includes a first connecting groove and a second connecting groove that are connected to each other, the first connecting groove is provided along a length direction of the tube body, one end thereof is communicated with the outside, and the second connecting groove is connected to one end, away from the base, of the first connecting groove, to be connected to the first connecting groove to form the bending portion with a preset bending angle.

Optionally, the bending angle of the bending portion is 90 degrees to 150 degrees.

Optionally, side walls of the tube body and the base are provided with a counter bore along a stacking direction, the protrusion portion includes a nut and a screw, the nut is clamped in the counter bore, and the screw is in threaded connection with the nut and protrudes from the side wall of the base.

Optionally, side walls of the tube body and the base are provided with a counter bore along a stacking direction, the protrusion portion includes a fixing end and an elastic telescopic rod, the fixing end is clamped in the counter bore, and an end portion of the elastic telescopic rod is connected to the fixing end and protrudes from the side wall of the base.

Optionally, the laser pen further includes a circuit assembly disposed in the accommodating cavity, and the circuit assembly is electrically connected to the laser diode; and the circuit assembly includes a circuit board and a battery that are arranged in the accommodating cavity in sequence, and the circuit board is electrically connected to the battery.

Optionally, an insulating sleeve is sleeved on an outer wall of the battery, and one end, close to the base, of the battery is provided with an insulating sheet.

Optionally, the side wall of the tube body is provided with a mounting hole, a switch button is mounted in the mounting hole, and an end portion of the switch button is connected to the circuit board, to control the laser diode to transmit or close a laser through the circuit board.

Optionally, the tube body includes a main body and a tube head, the main body is of the hollow structure, and the laser diode is disposed in the main body; the base is connected to one end of the main body; the tube head is in threaded connection with one end, away from the base, of the main body; and one end, away from the main body, of the tube head is provided with an opening, and the laser transmitted by the laser diode is emitted from the opening of the tube head.

Optionally, an end portion, away from the tube body, of the base is provided with a connecting portion, the connecting portion is provided with a connecting hole, and the connecting hole is configured to be provided with an external accessory in a penetrating manner.

Beneficial effects of the present invention are as follows:

The present application provides a laser pen, including a tube body and a base, where the tube body is of a hollow structure, and the base is connected to a first end of the tube body, to form an accommodating cavity; a laser diode configured to transmit a laser beam is disposed in the accommodating cavity, and the laser diode emits the laser beam from a second end of the tube body; the first end of the tube body is provided with at least one through groove, the through groove is provided with a bending portion, and one end thereof is communicated with the outside; and a side wall of the base is provided with a protrusion portion corresponding to the through groove, and the protrusion portion can be clamped in the bending portion of the through groove only by rotating the base at a certain angle, to enable the base to be connected to the tube body. According to the above laser pen obtained through design, the protrusion portion is matched with the through groove, so that loosening and separation between the base and the tube body and falling-off can be prevented, thereby improving connection stability between the base and the tube body and making assembly of the base and the tube body simple and convenient.

### BRIEF DESCRIPTION OF THE DRAWINGS

To describe the technical solutions in the embodiments of the present invention more clearly, the following briefly describes the accompanying drawings required for describing the embodiments. It should be understood that, the following accompanying drawings show merely some embodiments of the present invention, and therefore should not be regarded as a limitation on the scope. Those of ordinary skill in the art may still derive other related drawings from these accompanying drawings without creative efforts.

FIG. 1 is a schematic structural diagram 1 of a laser pen according to an embodiment of the present invention;

FIG. 2 is a schematic structural diagram of a base of a laser pen according to an embodiment of the present invention;

FIG. 3 is an exploded view of a base of a laser pen according to an embodiment of the present invention;

FIG. 4 is a schematic structural diagram of a main body of a tube body of a laser pen according to an embodiment of the present invention;

FIG. 5 is a schematic sectional view of a laser pen according to an embodiment of the present invention;

FIG. 6 is a schematic structural diagram 2 of a laser pen according to an embodiment of the present invention; and

FIG. 7 is a schematic structural diagram 3 of a laser pen according to an embodiment of the present invention.

Reference numerals: 100: laser pen; 110: tube body; 1101: main body; 1102: tube head; 1103: opening; 111: through groove; 1111: first connecting groove; 1112: second connecting groove; 112: battery; 113: insulating sleeve; 114: insulating sheet; 115: mounting hole; 116: switch button; 120: base; 121: protrusion portion; 1211: nut; 1212: screw; 122: counter bore; 123: connecting portion; 1231: connecting hole.

### DETAILED DESCRIPTION OF THE EMBODIMENTS

To make the objectives, technical solutions, and advantages of the embodiments of the present invention clearer, the following clearly and completely describes the technical solutions in the embodiments of the present invention with reference to the accompanying drawings in the embodiments of the present invention. Apparently, the described embodiments are some but not all of the embodiments of the present invention.

Generally, components, of the embodiments of the present invention, described and illustrated in the accompanying drawings herein may be arranged and designed in a variety of different configurations.

Therefore, the following detailed descriptions of the embodiments of the present invention provided in the accompanying drawings are not intended to limit the claimed protection scope of the present invention, but merely represent selected embodiments of the present invention. All other embodiments obtained by those of ordinary skill in the art based on the embodiments of the present invention without creative efforts shall fall within the protection scope of the present invention.

It should be noted that similar reference numerals and letters refer to similar items in the following accompanying drawings, and therefore, once an item is defined in one accompanying drawing, it is not necessary to further define and explain the item in the subsequent accompanying drawings.

In the description of the present invention, it should be noted that the orientations or positional relationships indicated by the terms “central”, “up”, “down”, “left”, “right”, “vertical”, “horizontal”, “inside”, “outside”, and the like are based on those shown in the accompanying drawings or are those normally placed when the invention product is used, intended only for the convenience of describing the present invention and for simplifying the description, and not intended to indicate or imply that the referred apparatus or element must be provided with a particular orientation or constructed and operated with a particular orientation, therefore not allowed to be construed as a limitation of the present invention. In addition, the terms “first”, “second”, “third”, and the like are merely used for distinguishing the description and not allowed to be construed as indicating or implicating relative importance.

In addition, the terms “horizontal”, “vertical”, and the like do not indicate that components are required to be absolutely horizontal or vertical, but may be slightly tilted. For example, “horizontal” merely indicates that a direction thereof is more horizontal relative to “vertical”, but does not indicate that the structure must be completely horizontal, but rather may be slightly tilted.

In the description of the present invention, it should be further noted that, unless otherwise explicitly provided and limited, the terms “disposed”, “mounted”, “attached”, and “connected” should be understood in a broad sense, e.g., it may be a fixed connection, a detachable connection, or an integral connection; it may be a mechanical connection or an electrical connection; it may be a direct connection or an indirect connection through an intermediate medium; and it may be a connection between two elements. For those of ordinary skill in the art, the specific meanings of the above terms in the present invention can be understood on a case-by-case basis.

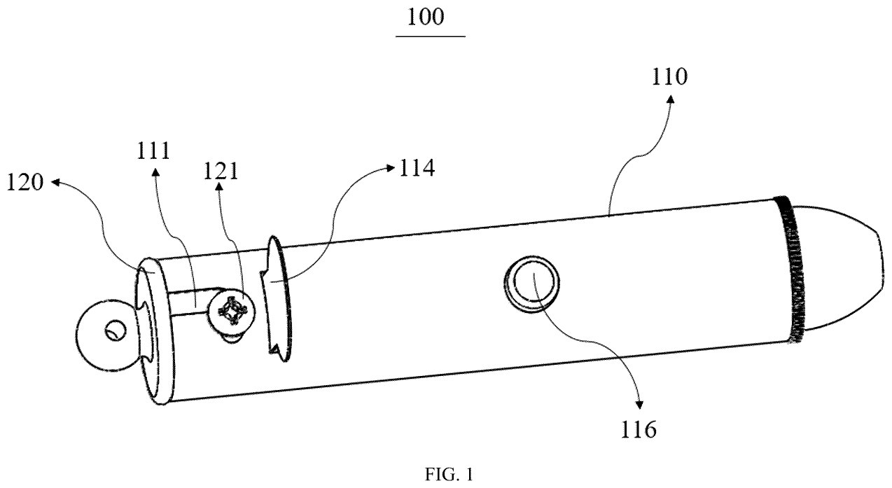

Referring to FIG. 1, an embodiment provides a laser pen 100, including a tube body 110 and a base 120, where the tube body 110 is of a hollow structure, and the base 120 is connected to a first end of the tube body 110, to form an accommodating cavity; a laser diode configured to transmit a laser beam is disposed in the accommodating cavity, and the laser diode emits the laser beam from a second end of the tube body 110; the first end of the tube body 110 is provided with at least one through groove 111, the through groove 111 is provided with a bending portion, and one end thereof is communicated with the outside; and a side wall of the base 120 is provided with a protrusion portion 121 corresponding to the through groove 111, and the protrusion portion 121 can be clamped in the bending portion of the through groove 111 to enable the base 120 to be connected to the tube body 110.

Specifically, the present application provides the laser pen 100 composed of two parts: the tube body 110 and the base 120, where the tube body 110 is of the hollow structure, so as to place required parts and components; a thickness of a housing of tube body 110 is 1 mm; and the base 120 is detachably connected to one end of the tube body 110, to enable the internal hollow structure of the tube body 110 to form a closed accommodating cavity, to prevent the internal parts and components from falling off. The laser diode is disposed in the accommodating cavity and is configured to transmit the laser beam, and one end, away from the base 120, of the tube body 110 is provided with an opening 1103, so that the laser diode can emit the laser beam from the end, away from the base 120, of the tube body 110 and may be configured for pet playing, teaching, speech, and the like.

One end, close to the base 120, of the tube body 110 is provided with the at least one through groove 111, the through groove 111 is of a bending structure, one end of the through groove is communicated with the outside through an edge of a side wall of the tube body 110, and the other end thereof is provided with the bending portion. Correspondingly, the side wall, in a direction of facing the side wall of the tube body 110, of the base 120 is provided with the protrusion portion 121 in a protruding manner, and the protrusion portion 121 can extend into the through groove 111 through one side, communicated with the outside, of the through groove 111. When the protrusion portion 121 extends into the bending portion of the through groove 111, the base 120 is rotated to enable the protrusion portion 121 to be clamped in the bending portion of the through groove 111. At this time, the base 120 is fixed to the tube body 110 in a clamping manner.

The protrusion portion 121 is matched with the base 120, so that the protrusion portion 121 needs to rotate at a certain angle to be clamped in the bending portion of the through groove 111. After the protrusion portion 121 is fixed to the through groove 111 in a clamping manner, the base 120 cannot be pulled out from the tube body 110, and the tube body 110 needs to rotate at a preset angle relative to the base 120, to ensure that the tube body 110 can be separated from the base 120 only after the protrusion portion 121 is separated from the bending portion of the through groove 111, so that assembly and disassembly are relatively simple and convenient and easy to operate.

According to an existing laser pen, a base is generally in threaded connection with a tube body, but a threaded connection manner is easy to result in loosening and separation between the base and the tube body, thereby resulting in falling-off of internal elements. According to the present application, the through groove 111 of the tube body 110 is matched with the protrusion portion 121 of the base 120, so that loosening and separation between the base 120 and the tube body 110 and falling-off can be prevented. Meanwhile, a design of a threaded structure is canceled, so that a structure of the tube body 110 is simple and subtle, a requirement for precision during production and manufacturing is relatively low, and production and manufacturing are easy.

It should be noted that the tube body 110 includes a main body 1101 and a tube head 1102, where the main body 1101 is of a hollow structure, and the laser diode is disposed in the main body 1101; the base 120 is connected to one end of the main body 1101; the tube head 1102 is in threaded connection with one end, away from the base 120, of the main body 1101; and one end, away from the main body 1101, of the tube head 1102 is provided with the opening 1103, and the laser beam transmitted by the laser diode is emitted from the opening 1103 of the tube head 1102.

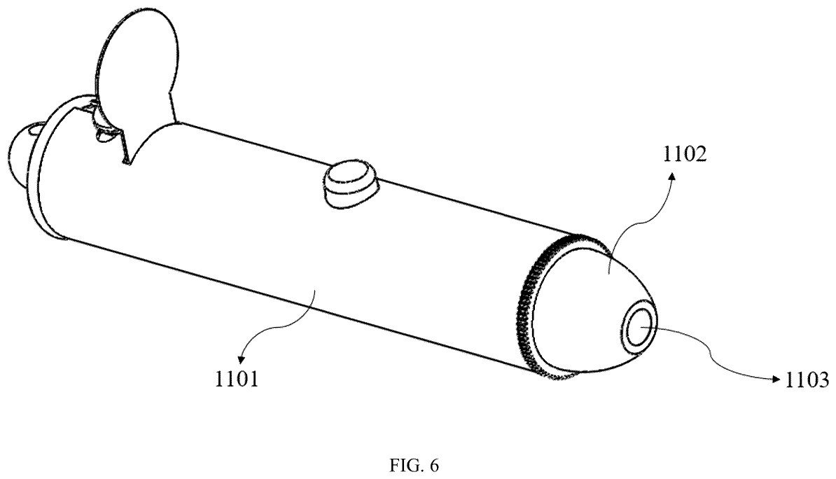

Specifically, as shown in FIG. 1 and FIG. 6, the tube body 110 includes two parts: the main body 1101 and the tube head 1102, where the main body 1101 is of the hollow structure, the tube head 1102 is preferably of a truncated cone structure, one end, away from the main body 1101, of the tube head is provided with the opening 1103, and the laser beam transmitted by the laser diode is emitted from the opening 1103 of the tube head 1102; and preferably, an inner diameter of the opening 1103 is less than that of the main body 1101, to improve a convergence effect of the laser beam. In an embodiment of the present application, the main body 1101 and the tube head 1102 may be of an integral structure; and in another embodiment, the tube head 1102 may be detachably connected to the main body 1101, and the tube head 1102 can be in threaded connection with one end, away from the base 120, of the main body 1101. Certainly, the tube head may also be connected to the end, away from the base, of the main body in a clamping manner and another detachable connecting manner.

The present application provides a laser pen 100, including a tube body 110 and a base 120, where the tube body 110 is of a hollow structure, and the base 120 is connected to a first end of the tube body 110, to form an accommodating cavity; a laser diode configured to transmit a laser beam is disposed in the accommodating cavity, and the laser diode emits the laser beam from a second end of the tube body 110; the first end of the tube body 110 is provided with at least one through groove 111, the through groove 111 is provided with a bending portion, and one end thereof is communicated with the outside; and a side wall of the base 120 is provided with a protrusion portion 121 corresponding to the through groove 111, and the protrusion portion 121 can be clamped in the bending portion of the through groove 111 only by rotating the base 120 at a certain angle, to enable the base 120 to be connected to the tube body 110. According to the above laser pen 100 obtained through design, the protrusion portion 121 is matched with the through groove 111, so that loosening and separation between the base 120 and the tube body 110 and falling-off can be prevented, thereby improving connection stability between the base 120 and the tube body 110 and making assembly of the base 120 and the tube body 110 simple and convenient.

Further, the through groove 111 includes a first connecting groove 1111 and a second connecting groove 1112 that are connected to each other, the first connecting groove 1111 is provided along a length direction of the tube body 110, one end thereof is communicated with the outside, and the second connecting groove 1112 is connected to one end, away from the base 120, of the first connecting groove 1111, to be connected to the first connecting groove 1111 to form the bending portion with a preset bending angle.

Further, the bending angle of the bending portion is 90 degrees to 150 degrees.

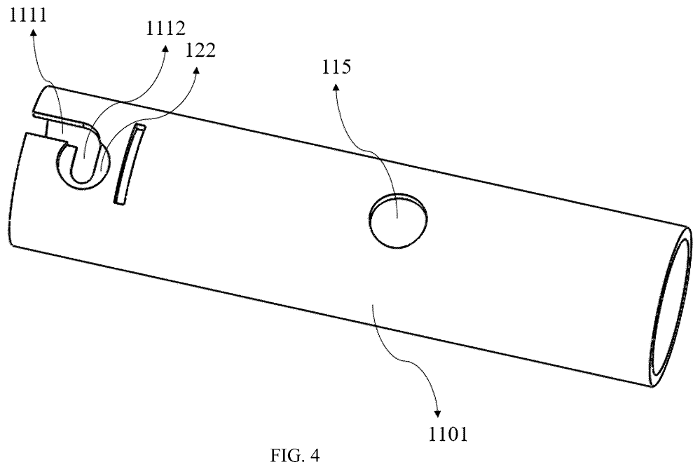

Specifically, as shown in FIG. 1 and FIG. 4, the through groove 111 includes the first connecting groove 1111 and the second connecting groove 1112, and the first connecting groove 1111 and the second connecting groove 1112 are connected to each other; the first connecting groove 1111 is provided along the length direction of the tube body 110, and one end thereof is communicated with the outside through the edge of the side wall of the tube body 110, so that the protrusion portion 121 can extend into the through groove 111 from the end; the second connecting groove 1112 is connected to one end, away from the base 120, of the first connecting groove 1111, and a certain bending angle is between the second connecting groove 1112 and the first through groove 1111, to form the bending portion; and the protrusion portion 121 can extend into the through groove 111 through one side, communicated with the outside, of the first connecting groove 1111. When the protrusion portion 121 extends into the bending portion at which the first connecting groove 1111 is connected to the second connecting groove 1112, the base 120 is rotated to enable the protrusion portion 121 to be clamped in the bending portion of the second connecting groove 1112. At this time, the base 120 is fixed to the tube body 110 in a clamping manner.

The bending angle of the bending portion is 90 degrees to 150 degrees. Preferably, as shown in FIG. 4, the bending angle is 90 degrees, and a clamping and fixing effect thereof is better.

In an embodiment of the present application, side walls of the tube body 110 and the base 120 are provided with a counter bore 122 along a stacking direction, the protrusion portion 121 includes a nut 1211 and a screw 1212, the nut 1211 is clamped in the counter bore 122, and the screw 1212 is in threaded connection with the nut 1211 and protrudes from the side wall of the base 120.

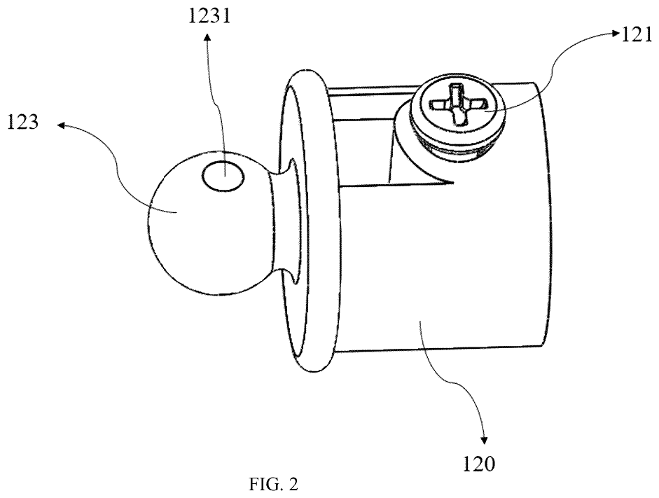

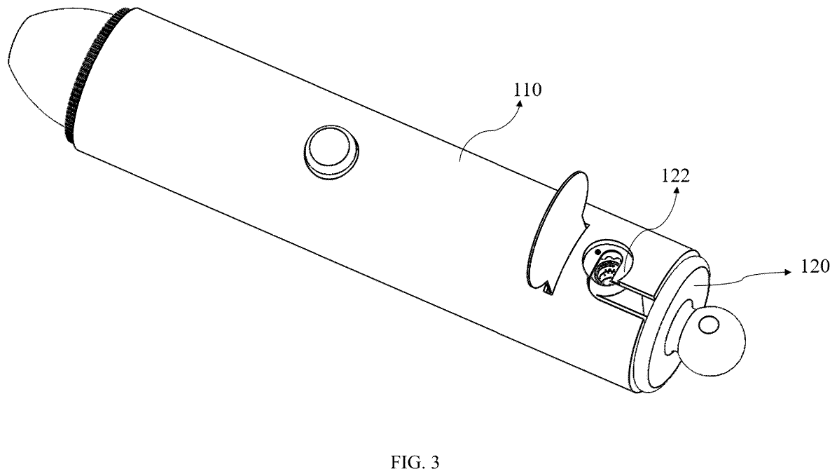

Specifically, as shown in FIG. 2 and FIG. 3, the side walls of the tube body 110 and the base 120 are provided with the counter bore 122 along the stacking direction, and the counter bore is used to be provided with the protrusion portion 121. The protrusion portion 121 includes two parts: the nut 1211 and the screw 1212, where the nut 1211 is clamped in the counter bore 122, one end of the screw 1212 is in threaded connection with the nut 1211, and the other end thereof protrudes from the side wall of the base 120, to facilitate clamping in the through groove 111. The nut 1211 is in threaded connection with the screw 1212, so that the protrusion portion 121 is connected more stably.

In another embodiment of the present application, side walls of the tube body 110 and the base 120 are provided with a counter bore 122 along a stacking direction, the protrusion portion 121 includes a fixing end and an elastic telescopic rod, the fixing end is clamped in the counter bore 122, and an end portion of the elastic telescopic rod is connected to the fixing end and protrudes from the side wall of the base 120.

Specifically, the side walls of the tube body 110 and the base 120 are provided with the counter bore 122 along the stacking direction, and the counter bore 122 is used to be provided with the protrusion portion 121. The protrusion portion 121 includes the fixing end and the elastic telescopic rod, where the fixing end is clamped in the counter bore 122, one end of the elastic telescopic rod is connected to the fixing end, and the other end thereof protrudes from the side wall of the base 120, to facilitating clamping in the through groove 111. The protrusion portion 121 is disposed in a form that can be elastically telescopic, so that an elastic telescopic rod may be retracted under pressure of the side wall of the tube body 110 in a process that the base 120 is assembled to the tube body 110. At this time, the protrusion portion 121 can reach a position of the bending portion of the through groove 111 without using the first connecting groove 1111. When the protrusion portion 121 reaches the second connecting groove 1112, the protrusion portion resets and protrudes without the pressure of the side wall of the tube body 110, to be clamped with the through groove 111. According to this disposing manner, mounting of the base 120 and the tube body 110 can be further simplified, the base 120 does not need to rotate relative to the tube body 110, and assembly of the base 120 and the tube body 110 is simple and convenient.

According to the above embodiments, the two protrusion portions both can be connected to the tube body 110 through the counter bore 122, and the counter bore 122 can orient the protrusion portion 121, further improving connection stability between the protrusion portion 121 and the tube body 110 and the base 120.

For example, the laser pen 100 further includes a circuit assembly disposed in the accommodating cavity, and the circuit assembly is electrically connected to the laser diode; and the circuit assembly includes a circuit board and a battery 112 that are arranged in the accommodating cavity in sequence, and the circuit board is electrically connected to the battery 112.

Specifically, the laser pen 100 further includes the circuit assembly (not shown in the figure), the circuit assembly is disposed in the accommodating cavity of the tube body 110, and the circuit assembly is electrically connected to the laser diode, to control a working state of the laser diode. The circuit assembly includes the circuit board and the battery 112, and the circuit board is electrically connected to the battery 112; and the battery 112 is configured to supply electric energy to the laser diode, and the circuit board is configured to control the working state of the laser diode. Preferably, the battery 112 may be a detachable coin battery 112, the battery 112 may be disposed on one side close to the base 120, and the battery 112 can be replaced by detaching the base 120.

Further, an insulating sleeve 113 is sleeved on an outer wall of the battery 112, and one end, close to the base 120, of the battery 112 is provided with an insulating sheet 114.

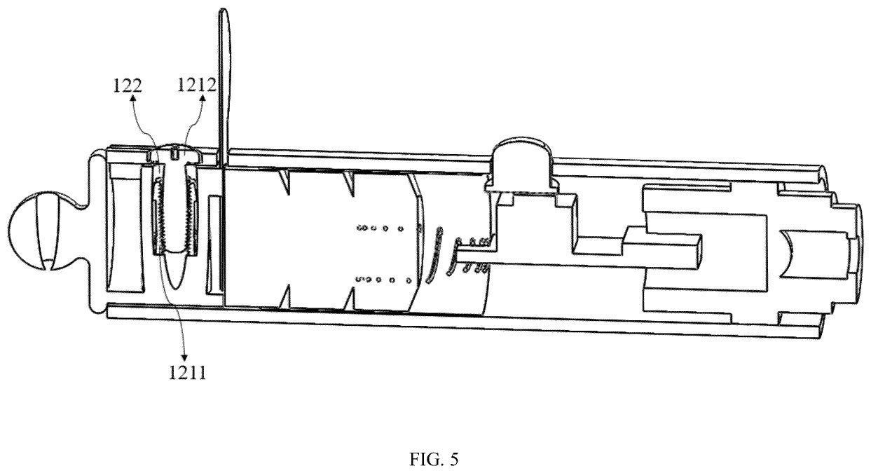

Specifically, as shown in FIG. 5, the insulating sleeve 113 is sleeved on the outer wall of the battery 112, and the insulating sleeve 113 can insulate the battery 112, prevent an external short circuit of the battery 112 and water seepage, and have another effect; and one end, close to the base 120, of the battery 112 is provided with the insulating sheet 114, to isolate contact between an internal metal member of the battery 112 and the external tube body 110 or another metal member, thereby further improving use reliability of the laser pen 100.

Further, the side wall of the tube body 110 is provided with a mounting hole 115, a switch button 116 is mounted in the mounting hole 115, and an end portion of the switch button 116 is connected to the circuit board, to control the laser diode to transmit or close a laser through the circuit board.

Specifically, as shown in FIG. 1 and FIG. 4, the side wall of the tube body 110 is provided with the mounting hole 115, the mounting hole 115 is configured to be provided with the switch button 116, the end portion of the switch button 116 is connected to the circuit board of the circuit assembly, and the working state of the laser diode can be controlled through the circuit board by pressing the switch button 116, to enable the laser pen 100 to transmit or close the laser. Certainly, in addition to the press-type switch button 116, a toggle-type switch button 116 may further be disposed. A specific use manner of the switch button 116 is not limited in the present application.

Further, an end portion, away from the tube body 110, of the base 120 is provided with a connecting portion 123, the connecting portion 123 is provided with a connecting hole 1231, and the connecting hole 1231 is configured to be provided with an external accessory in a penetrating manner.

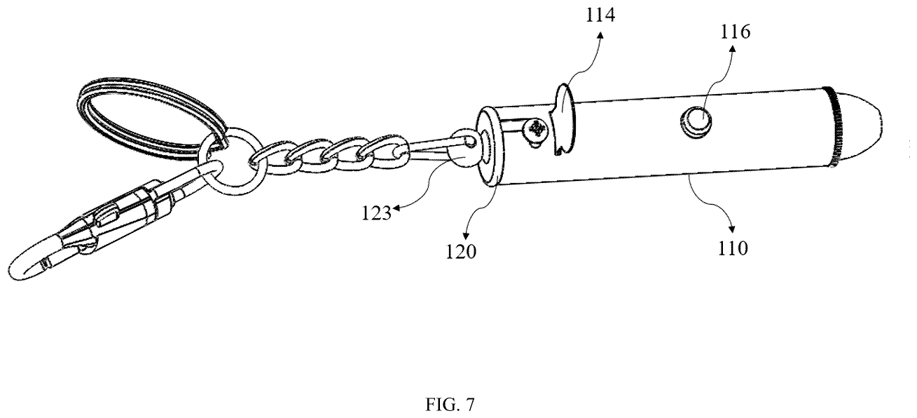

Specifically, as shown in FIG. 2 and FIG. 7, the end portion, away from the tube body 110, of the base 120 is further provided with the connecting portion 123, the connecting portion 123 is provided with the connecting hole 1231, and the connecting hole 1231 can be provided with a keychain, a hanging rope, and another external accessory in a penetrating manner, to prevent the laser pen 100 from falling off.

The above descriptions are merely optional embodiments of the present invention, but are not intended to limit the present invention. For a person skilled in the art, the present invention may have various modifications and variations. Any modifications, equivalent replacements, improvements, and the like made within the spirit and principle of the present invention shall fall within the protection scope of the present invention.

In addition, it should be noted that the specific technical features described in the above specific embodiments may be combined in any proper manner if there is no conflict. To avoid unnecessary repetition, various possible combinations are not further described in the present invention.

What is claimed is:

1. A laser pen, comprising a tube body and a base, wherein the tube body is of a hollow structure, and the base is connected to a first end of the tube body, to form an accommodating cavity; a laser diode configured to transmit a laser beam is disposed in the accommodating cavity, and the laser diode emits the laser beam from a second end of the tube body; the first end of the tube body is provided with at least one through groove, the through groove is provided with a bending portion, and one end thereof is communicated with outside; and a side wall of the base is provided with a protrusion portion corresponding to the through groove, and the protrusion portion can be clamped in the bending portion of the through groove to enable the base to be connected to the tube body.

2. The laser pen according to claim 1, wherein the through groove comprises a first connecting groove and a second connecting groove that are connected to each other, the first connecting groove is provided along a length direction of the tube body, one end thereof is communicated with the outside, and the second connecting groove is connected to one end, away from the base, of the first connecting groove, to be connected to the first connecting groove to form the bending portion with a preset bending angle.

3. The laser pen according to claim 2, wherein the bending angle of the bending portion is 90 degrees to 150 degrees.

4. The laser pen according to claim 2, wherein side walls of the tube body and the base are provided with a counter bore along a stacking direction, the protrusion portion comprises a nut and a screw, the nut is clamped in the counter bore, and the screw is in threaded connection with the nut and protrudes from the side wall of the base.

5. The laser pen according to claim 2, wherein side walls of the tube body and the base are provided with a counter bore along a stacking direction, the protrusion portion comprises a fixing end and an elastic telescopic rod, the fixing end is clamped in the counter bore, and an end portion of the elastic telescopic rod is connected to the fixing end and protrudes from the side wall of the base.

6. The laser pen according to claim 1, wherein the laser pen further comprises a circuit assembly disposed in the accommodating cavity, and the circuit assembly is electrically connected to the laser diode; and the circuit assembly comprises a circuit board and a battery that are arranged in the accommodating cavity in sequence, and the circuit board is electrically connected to the battery.

7. The laser pen according to claim 6, wherein an insulating sleeve is sleeved on an outer wall of the battery, and one end, close to the base, of the battery is provided with an insulating sheet.

8. The laser pen according to claim 6, wherein a side wall of the tube body is provided with a mounting hole, a switch button is mounted in the mounting hole, and an end portion of the switch button is connected to the circuit board, to control the laser diode to transmit or close a laser through the circuit board.

9. The laser pen according to claim 1, wherein the tube body comprises a main body and a tube head, the main body is of the hollow structure, and the laser diode is disposed in the main body; the base is connected to one end of the main body; the tube head is in threaded connection with one end, away from the base, of the main body; and one end, away from the main body, of the tube head is provided with an opening, and a laser transmitted by the laser diode is emitted from the opening of the tube head.

10. The laser pen according to claim 1, wherein an end portion, away from the tube body, of the base is provided with a connecting portion, the connecting portion is provided with a connecting hole, and the connecting hole is configured to be provided with an external accessory in a penetrating manner.
